(19) United States
(12) Patent Application Publication
(10) Pub. No.: US 2006/0062913 A1
(43) Pub. Date: Mar. 23, 2006

(54) PROCESS FOR DEPOSITING BTBAS-BASED SILICON NITRIDE FILMS

(76) Inventors: Yun-Ren Wang, Tai-Nan City (TW); Ying-Wei Yen, Miao- Li Hsien (TW); Hao-Hsiang Chang, Kao-Hsiung City (TW); Tsai-Fu Hsiao, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/711,414

(22) Filed: Sep. 17, 2004

(51) Int. Cl. C23C 16/00

(52) U.S. Cl. 427/248.1; 118/715

(57) ABSTRACT

A chemical vapor deposition (CVD) system comprises a tubular furnace, at least one BTBAS supply piping line connected to a base portion of the tubular furnace, an exhaust piping line connected to an upper portion of the tubular furnace, a bypass line connecting the BTBAS supply piping line with the exhaust piping line, and a vacuum pump connected to the exhaust piping line, wherein the bypass line is initially interrupted. A batch of wafers is placed into a tube of the tubular furnace. Nitrogen-containing gas and carrier gas are flowed into the tube. BTBAS is flowed into the tube through the BTBAS supply piping line. A silicon nitride deposition process is then carried out in the tube to deposit a BTBAS-based silicon nitride film on the wafers. Upon completion of the silicon nitride deposition process, the BTBAS supply piping line is blocked and the initially interrupted bypass line is opened.

### BACKGROUND OF INVENTION

1. Field of the Invention

The present invention relates to the field of low-pressure chemical vapor deposition (LPCVD) of silicon nitride films, and more particularly to an improved process and system for depositing BTBAS-based silicon nitride films on wafers.

2. Description of the Prior Art

Semiconductor devices are fabricated using a sequence of process steps some of which are low-pressure chemical vapor deposition (LPCVD) of silicon nitride. LPCVD nitride films are typically deposited by thermally reacting dichlorosilane (DCS) and NH₃ at temperatures of approximately 750° C. At smaller feature size (<0.10 mm) advanced semiconductor devices require a reduction of thermal budget for process involved with the gate stack and sidewall spacers.

A lower temperature CVD method of depositing silicon nitride is to use an organic precursor, BTBAS (bis t-ButylaminoSilane). A typical BTBAS process utilizes SiH₂(t-BuNH)₂ along with NH₃ and other gases such as nitrogen to deposit the silicon nitride at temperatures between 475° C. and 650° C. However this process can result in high particle levels on device wafers.

While BTBAS films have a lower thermal budget (the deposition temperature is approximately 550-575° C.), the intrinsic film stress is significantly higher than for DCS films. Higher stress films require more frequent cleaning of the LPCVD furnace to prevent particle shedding. Typically, LPCVD furnaces are cleaned after a cumulative deposition to a thickness of approximately 20-40 μm on the chamber walls. Because of the higher film stress, BTBAS furnaces must be cleaned after a cumulative deposition of 0.25-0.35 μm. (ex. 5 to 7 runs for 50 nm depositions).

Current practice for cleaning LPCVD Si₃N₄ tubes involves, by way of example, cooling then removing the quartz tube from the furnace followed by wet etching with aqueous HF. The wet clean ordinarily requires 8 to 24 hours of equipment downtime. The production schedule including cleaning the BTBAS furnaces after 2 days operation would result in low system availability and reduced throughput.

Accordingly, a need exists in this industry for a solution of the aforesaid particle problem for BTBAS films to be practical in semiconductor manufacturing. There is also a need to provide a method of fast and effectively cleaning the BTBAS furnaces and tubes, thereby increasing uptime of LPCVD equipments.

### SUMMARY OF INVENTION

It is therefore the primary object of the present invention to provide an improved process and system for depositing BTBAS-based silicon nitride films on wafers.

According to the claimed invention, a process for depositing silicon nitride films on wafers is provided. A chemical vapor deposition (CVD) system is prepared. The CVD system comprises a tubular furnace, at least one BTBAS (bis t-ButylaminoSilane) supply piping line connected to a base portion of the tubular furnace, an exhaust piping line connected to an upper portion of the tubular furnace, a bypass line connecting the BTBAS supply piping line with the exhaust piping line, and a vacuum pump connected to the exhaust piping line, wherein the bypass line is initially interrupted. A batch of wafers is then placed into a tube of the tubular furnace. Nitrogen-containing gas and carrier gas are flowed into the tube. BTBAS is flowed into the tube through the BTBAS supply piping line. The vacuum pump maintains pressure in the tube in a range of between about 0.1 Torr and 3 Torr. A silicon nitride deposition process is then carried out in the tube to deposit a BTBAS-based silicon nitride film on the wafers. Upon completion of the silicon nitride deposition process, the BTBAS supply piping line is blocked and the initially interrupted bypass line is now opened. The batch of wafers are removed.

From one aspect of the present invention, a chemical vapor deposition (CVD) furnace system for performing a silicon nitride deposition process on wafers is disclosed. The CVD furnace system comprises a tubular furnace comprising a tube for accommodating a batch of wafers; at least one BTBAS (bis t-ButylaminoSilane) supply piping line connected to a base portion of the tubular furnace; an exhaust piping line connected to an upper portion of the tubular furnace; a bypass line connecting the BTBAS supply piping line and the exhaust piping line; and a vacuum pump connected to the exhaust piping line, wherein the bypass line is initially interrupted, and upon completion of the silicon nitride deposition process, the BTBAS supply piping line is interrupted and the initially interrupted bypass line is opened.

It is one advantage of this invention that by opening the initially interrupted bypass line upon completion of the silicon nitride deposition process, the BTBAS remaining in the BTBAS supply piping line is evacuated through the bypass line without entering the tubular furnace. Consequently, particle problems can be significantly improved.

Other objects, advantages and novel features of the invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic diagram illustrating a LPCVD system for depositing BABAS-based silicon nitride films on wafers in accordance with one preferred embodiment of the present invention; and

FIG. 2 is a flow chart demonstrating the main process steps according to the preferred embodiment of this invention.

### DETAILED DESCRIPTION

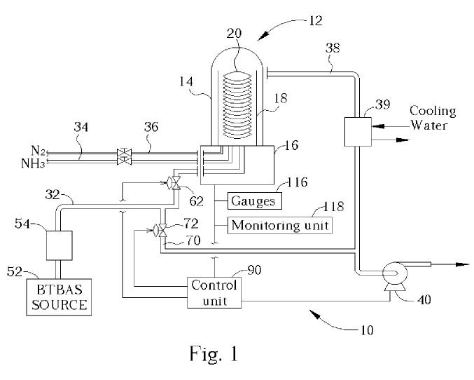

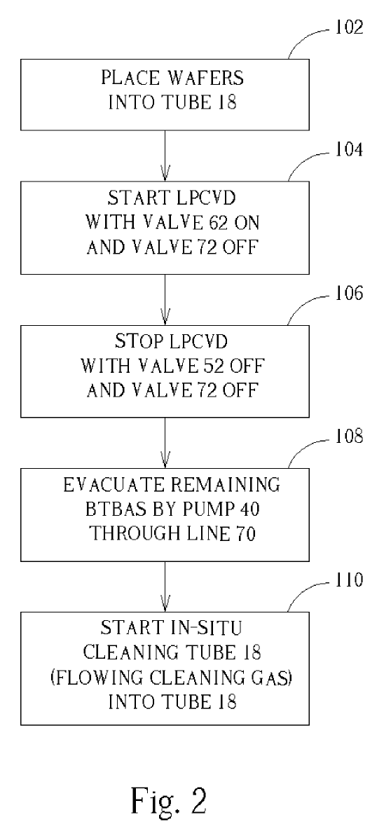

The present invention pertains to LPCVD deposition of BTBAS-based silicon nitride films and an improved LPCVD system for depositing such silicon nitride films on semiconductor wafers. As aforementioned, particle problems associated with prior art LPCVD deposition methods are severe and still remain unsolved, which therefore cause chip manufacturers to suffer lengthy equipment downtime and reduced throughput. The present invention proposes an inexpensive and effective method and LPCVD system to alleviate or eliminate the aforesaid particle problems. One advantage of the present invention is that the equipment downtime and throughput are improved. A preferred embodiment will now be explained with reference to FIG. 1 and FIG. 2.

FIG. 1 is a schematic diagram illustrating a LPCVD system 10 for depositing BABAS-based silicon nitride films on wafers in accordance with one preferred embodiment of the present invention. The BTBAS silicon nitride process is suitable for forming sidewall spacers of metal-oxide-semiconductor (MOS) transistors at relatively low temperatures. As shown in FIG. 1, the LPCVD system 10 comprises a tubular furnace 12 comprising a vessel housing 14, a base portion 16, and a tube 18 installed inside the vessel housing 14. A batch of wafers 20, which may be placed in a wafer boat (not explicitly shown), are situated in the tube 18. The tube 18 may be made of quartz or the like.

Processing substances including precursor gas such as gaseous BTBAS (bis t-ButylaminoSilane), gaseous ammonia, and carrier gas such as nitrogen flow into the tube 18 from piping lines 32, 34, and 36, respectively. These piping lines 32, 34, and 36 are typically connected to the base portion 16 of the furnace 12 with flanges and sealing rings, but not limited thereto. A BTBAS supply unit or BTBAS source 52 is communicated with the piping line 32. The BTBAS is originally in liquid state and is pre-heated to about 80° C. at the BTBAS source 52. The BTBAS is initially bubbled into the piping line 32 with inert gas, ex. helium (He), and then vaporized at 130° C.˜150° C. by a vaporizer 54 installed on the piping line 32. It is to be understood that in order to maintain the BTBAS in a vapor state a heating jacket (not shown) may be wrapped around the piping line 32. Further, it is to be understood that the base portion 16 in FIG. 1 is simplified and is only for illustration purposes. Gauges 116, analysis instruments, or in-situ monitoring unit 118 may be incorporated with the base portion 16.

The aforesaid processing substances, which are injected into the tube 18, flow out of the furnace 12 through the exhaust piping line 38, which is installed at an upper portion of the furnace 12. The exhaust piping line 38 is connected to a vacuum pump 40, which maintains the vacuum of the furnace 12 during a silicon nitride CVD process. A cooling water system 39 may be provided to the exhaust piping line 38 for cooling down the evacuated gas mixture passing through the exhaust piping line 38, thereby protecting the vacuum pump 40.

The present invention LPCVD system 10 features that a bypass line 70 is deliberately provided to connect the BTBAS supply piping line 32 with the exhaust piping line 38. A control valve 62 is installed on the piping line 32. The control valve 62 is preferably situated adjacent to the base portion 16 as near as possible. A control valve 72 is installed on the bypass line 70. Both of the control valves 62 and 72 are controlled by a control unit 90, which may also control the recipe, flow rates of processing gases, and the vacuum pump 40.

During the silicon nitride CVD process, the control valve 62 is on, while the control valve 72 is turned off such that BTBAS gas is flowed into the furnace 12. Upon the completion of the silicon nitride CVD process, the control valve 62 is off, and the control valve 72 is turned on. By doing this, the gaseous BTBAS substances remaining in the piping line 32 will not enter the furnace 12 in the following tube in-situ cleaning process. The remaining gaseous BTBAS substances are evacuated from the LPCVD system 10 by way of the bypass line 70 instead of by way of the furnace 12, thereby alleviating or preventing the particle problems. For the aforesaid in-situ cleaning process, cleaning gases such as ClF₃/N₂, NF₃/N₂ or the like may be flowed into the tube 18. The decomposed F species will react with the CVD residues in the tube 18, and then evacuated by the vacuum pump 40. Of course, before the in-situ cleaning process the batch of wafers 20 has been removed. The cleaning process is known in the art and the details thereof are thus omitted hereinafter.

Please refer to FIG. 2 and briefly back to FIG. 1. FIG. 2 is a flow chart demonstrating the main process steps according to the preferred embodiment of this invention. As shown in FIG. 2, in Step 102, a batch of wafers 20 are placed into the tube 18 of the furnace 12. In Step 104, a low-pressure chemical vapor deposition (LPCVD) is performed with the control valve 62 on, but the control valve 72 off. At this phase, a BTBAS silicon nitride process is carried out in the tube 18 including the following conditions: temperature between 450° C.˜600° C.; pressure between 0.1˜3.0 Torr; BTBAS flow rate between 25˜500 sccm; and NH₃ flow rate between 50˜1000 sccm. In Step 106, after a pre-determined thickness of BTBAS-based silicon nitride films is deposited onto the wafer, the LPCVD is terminated. At this phase, the control valve 62 is off, while the control valve 72 is now turned on. In Step 108, the remaining gaseous BTBAS substances in the piping line 32 are evacuated by pump 40 through the bypass line 70. In Step 110, an in-situ tube cleaning process is carried out. Cleaning gas is flowed into the tube 18.

In light of the above, benefits of this invention at least include:

(1) PM and dummy wafers exchange cycle time can be extended due to decreased particles.

(2) Process windows for lithography aspect can be wider and phenomenon of broken metal line can be minimized, and therefore, yield rate can be improved.

(3) The feasibility of the BTBAS precursor can be extended to next generation applications.

Those skilled in the art will readily observe that numerous modification and alterations of the invention may be made while retaining the teachings of the invention. Accordingly, the above disclosure should be construed as limited only by the metes and bounds of the appended claims.

What is claimed is:

1. A process for depositing silicon nitride films on wafers, comprising:
providing a chemical vapor deposition (CVD) system comprising a tubular furnace, at least one BTBAS (bis t-ButylaminoSilane) supply piping line connected to a base portion of said tubular furnace, an exhaust piping line connected to an upper portion of said tubular furnace, a bypass line connecting said BTBAS supply piping line with said exhaust piping line, and a vacuum pump connected to said exhaust piping line, wherein said bypass line is initially interrupted;
placing a batch of wafers into a tube of said tubular furnace;
flowing nitrogen-containing gas into said tube;
flowing BTBAS into said tube through said BTBAS supply piping line and said vacuum pump maintaining pressure in said tube in a range of between about 0.1 Torr and 3 Torr;
performing a silicon nitride deposition process in said tube to deposit a BTBAS-based silicon nitride film on said wafers;
upon completion of said silicon nitride deposition process, interrupting said BTBAS supply piping line and opening said initially interrupted bypass line; and
removing said batch of wafers.

2. The process for depositing silicon nitride films on wafers according to claim 1 wherein after removing said batch of wafers, the process further comprises flowing cleaning gas into said tube.

3. The process for depositing silicon nitride films on wafers according to claim 2 wherein said cleaning gas comprises ClF₃.

4. The process for depositing silicon nitride films on wafers according to claim 2 wherein said cleaning gas comprises NF₃.

5. The process for depositing silicon nitride films on wafers according to claim 1 wherein by opening said initially interrupted bypass line upon completion of said silicon nitride deposition process, said BTBAS remaining in said BTBAS supply piping line is evacuated through said bypass line without entering said tubular furnace, thereby eliminating particle problems.

6. The process for depositing silicon nitride films on wafers according to claim 1 wherein said nitrogen-containing gas comprises ammonia gas.

7. The process for depositing silicon nitride films on wafers according to claim 1 wherein silicon nitride deposition process is carried out at a temperature of between 450˜600° C.

8. The process for depositing silicon nitride films on wafers according to claim 1 wherein said BTBAS is flowed into said tube at a flow rate of about 25˜500 sccm.

9. The process for depositing silicon nitride films on wafers according to claim 1 wherein said nitrogen-containing gas is flowed into said tube at a flow rate of about 50˜1000 sccm.

10. A chemical vapor deposition (CVD) furnace system for performing a silicon nitride deposition process on wafers, comprising:
a tubular furnace comprising a tube for accommodating a batch of wafers;
at least one BTBAS (bis t-ButylaminoSilane) supply piping line connected to a base portion of said tubular furnace;
an exhaust piping line connected to an upper portion of said tubular furnace;
a bypass line connecting said BTBAS supply piping line and said exhaust piping line; and
a vacuum pump connected to said exhaust piping line, wherein said bypass line is initially interrupted, and upon completion of said silicon nitride deposition process, said BTBAS supply piping line is interrupted and said initially interrupted bypass line is opened.

11. The CVD furnace system for performing a silicon nitride deposition process on wafers according to claim 10 wherein said tube is made of quartz.

12. The CVD furnace system for performing a silicon nitride deposition process on wafers according to claim 10 wherein said silicon nitride deposition process is carried out under a pressure in a range of between about 0.1 Torr and 3 Torr.

13. The CVD furnace system for performing a silicon nitride deposition process on wafers according to claim 10 wherein said silicon nitride deposition process is carried out at a temperature of between 450˜600° C.

14. The CVD furnace system for performing a silicon nitride deposition process on wafers according to claim 10 wherein said bypass line is interrupted by means of a control valve.

15. The CVD furnace system for performing a silicon nitride deposition process on wafers according to claim 10 wherein by opening said initially interrupted bypass line upon completion of said silicon nitride deposition process, said BTBAS remaining in said BTBAS supply piping line is evacuated through said bypass line without entering said tubular furnace, thereby eliminating particle problems.
